(19) United States
(12) Patent Application Publication
(10) Pub. No.: US 2018/0291501 A1
(43) Pub. Date: Oct. 11, 2018

(54) ANTI-STRESS COATING FOR PROCESS CHAMBER SHIELDING SYSTEM

(71) Applicant: NOVENA TEC INC., Markham (CA)

(72) Inventors: Rommel MONTES, Calgary (CA); Rajan THIRU, Markham (CA); Ravi THIRUN, Markham (CA)

(73) Assignee: NOVENA TEC INC., Markham, ON (CA)

(21) Appl. No.: 15/754,265

(22) PCT Filed: Aug. 22, 2016
(86) PCT No.: PCT/CA2016/050987

§ 371 Date: Feb. 21, 2018

Related U.S. Application Data
(60) Provisional application No. 62/208,613, filed on Aug. 22, 2015.

(30) Foreign Application Priority Data
Jun. 13, 2016 (CA) PCT/CA2016/050675

(51) Int. Cl. C23C 16/44; C23C 14/56

(52) U.S. Cl. CPC C23C 16/4404; C23C 14/564

(57) ABSTRACT

A coating for protecting a base material, such as a process chamber component, from an excess material film resulting from operation of a process chamber. The coating including a sheet for receiving the excess material deposited during the operation. In some aspects the sheet may be structured to provide at least one of stress relief and defect prevention in the deposited excess material. The sheet structure may include at least one of folds, ribs, and bi-facial curves in the sheet. In an aspect, the sheet may be patterned to provide improved adhesion of the deposited excess material. A plurality of joints for securing the at least one sheet at joint locations to the base material. In some aspects, a method and system are provided for protecting process chamber components.

### CROSS-REFERENCE OF RELATED APPLICATION

This application claims priority to U.S. Provisional Patent Application Ser. No. 62/208,613 filed on Aug. 22, 2015, and to PCT Patent Application No. CA2016050675 filed on Jun. 13, 2016, the contents of which are incorporated entirely herein by reference.

### FIELD

The following relates generally to process chambers for thin film deposition in semiconductor fabrication, and more particularly to an improved system and method for shielding the various components of a process chamber.

### BACKGROUND

Physical vapour deposition (PVD), otherwise known as sputtering, is a process by which a thin film of material may be deposited on a substrate during the fabrication of semiconductors. PVD is a plasma process conducted within a vacuum process chamber, and involves bombarding a target with ions to cause the target to eject atoms. The ejected atoms build up as a deposited film on an intended semiconductor substrate being supported within the process chamber.

Chemical Vapour Deposition (CVD) is a process used to produce high quality, high-performance, solid materials. The process is often used in the semiconductor industry to produce very uniform thin film deposition. This thin film deposition is generated by higher temperature, pressure, and plasma causing a chemical reaction.

Excess material resulting from overspray of the released material condensing and accumulating in the chamber during operation tends to also deposit on various parts of the apparatus, such as the showerhead and other parts within the process cavity. The excess material tends to build up over time, creating a thin excess material film on interior surfaces of the process chamber. The excess material film builds up and thickens over time to a point that mechanical stresses within the excess material film may cause the excess material film to weaken and pieces or flakes of the film eventually break away into the process chamber and come into contact with a substrate where a new deposition is being attempted, Typically, material may flake off during changes in the process environment such as during wafer transfer operations, or quick pressure changes induced by switching gas flow.

These unwanted flakes interfere with and contaminate the deposition process, which can result in serious degradation of the quality of the new thin film that is intended to be deposited on the wafer. As such, in order to maintain quality of deposited films, it is well known from time to time to take the process chamber temporarily out of service for cleaning by removing excess material film that has built up on process chamber components since the last cleaning.

In order to ease the cleaning process, it is well-known to employ a collection of shielding components within the process chamber. Shielding components (commonly referred to as “process kit components”) including sidewall shields, bottom shield, outer and inner shields, deposition rings, cover ring, dummy wafer and any other shielding components that define the process chamber cavity, are often used to protect the permanent structural components of the process chamber. The operational life of these shielding components is typically a product of the stability of the excess material film as it builds up over time. The shielding components are generally removably positioned within the process chamber and are configured in shape and size to both channel the ejected atoms towards the substrate and to somewhat shield more permanent structural components of the process chamber including the process chamber walls from excess material film build-up. Because the shielding components are removable they may be removed from the process chamber for cleaning or disposal, and replaced with clean shielding components so that the process chamber may be returned to service.

It is known to treat the surfaces of shielding components by abrading the surfaces using arc spray or bead blasting to enhance the ability for stray ejected atoms to adhere to the shielding components, creating a more stable excess material film on the shielding component surfaces. The goal being to present a receptive roughened surface that provides a stable substrate for building a thin excess material film of the stray ejected atoms, increasing the useful operational run life of the components during which the excess material film is stable and does not flake away in the process chamber during operation. Treating the shielding components surfaces in this manner provides for longer intervals between cleanings. The known surface treatments improve the adhesion of the excess material film, allowing for longer operational runs, but does not eliminate the need to periodically remove the excess material film from the process chamber.

Typically, the excess material film may be removed from the process chamber by removing the shielding components from the process chamber after the useful operational run life and replacing them with new/clean shielding components. In some cases, the process chamber walls may also require cleaning to remove built-up excess material using techniques such as polishing, bead blasting, and/or chemical/electro-chemical treatment.

The used shielding components may either be discarded for material recycling, or in some cases may be treated to clean their surfaces. In cases where the shielding components are cleaned, the used shielding components are typically treated by polishing, bead blasting, and/or chemical/electro-chemical treatment. After removal of the excess material film, the surface treatment may be re-administered to the component surfaces for re-use of the cleaned and treated shielding component. The cleaning process is time consuming, typically requiring rotation of one or more process kits in service while previously used process kits are off-line during the cleaning process. Accordingly, it is advantageous to extend the operational life of the shielding components as long as possible. Furthermore, the operational life is typically an estimation as the stability and subsequent flaking of the excess material film is a statistical process. Accordingly, the operational life is selected to minimize the risk of flaking, and subsequent disruption of process chamber operations.

There is a need for a process chamber shielding system and method that avoids limitations of the prior art. There is further a need for a system and method to extend the operational life of shielding components within a process chamber.

### SUMMARY

In an aspect, a coating for protecting process chamber shielding components, including process kit components, from excess material is provided. The coating protecting a base material, such as a process chamber shielding component, from an excess material film resulting from operation of a process chamber. The coating including a sheet for receiving the excess material deposited during the operation. In some aspects the sheet may be structured to provide at least one of stress relief and defect prevention in the deposited excess material. The sheet structure may include, for instance, at least one of folds, ribs, and bi-facial curves in the sheet. In an aspect the structure provides stress relief by providing flexibility in the sheet to accommodate flexion of the sheet. In an aspect the structure provides stress relief by providing extendibility in the sheet to accommodate differing expansion between material composition of the sheet and that of the underlying base material. In an aspect the structure provides defect prevention by ensuring the shortest path between any two points on the sheet is a curved path. In an aspect, the sheet may be patterned to provide improved adhesion of the deposited excess material to the sheet. A plurality of joints may be provided for securing the sheet at joint locations to the base material. The joints may be spot welds. The joints may be sheet structures such as folds in the sheet. In some aspects, a method and system are provided for protecting process chamber components.

In an implementation a coating is provided for protecting a base material within a process chamber from excess material deposited during operation of the process chamber. The coating includes a sheet for receiving excess material, the sheet structured to provide at least one of stress relief and defect prevention; and, a plurality of joints for securing the sheet at joint locations to a base material; wherein the coating sheet may be secured to the base material by securing the plurality of joints to the base material. In an aspect the sheet structure comprises at least one of: folds; ribs; and, bi-facial curves. In an aspect one or more of the plurality of joints comprise folds in the sheet. In an aspect the plurality of joints are secured to the base material by spot welding. The spot welds may be removable. In an aspect the sheet includes a combination of at least two structures. In an aspect the sheet includes as joints folds at one or more of the plurality of joint locations, and at least one of folds, ribs, and bi-facial curves between joint locations. In an aspect the coating includes folds along edges of the sheet.

In an implementation a shielding component for a process chamber is provided. The shielding component including base material shaped as a shielding component; a coating covering at least a portion of the base material, the coating comprising: at least one sheet for receiving excess material, the sheet structured to provide at least one of stress relief and defect prevention; and, a plurality of joints securing the sheet at joint locations to base material. In an aspect the sheet structure comprises at least one of: folds; ribs; and, bi-facial curves. In an aspect one or more of the plurality of joints comprise folds in the sheet. The folds may then be spot welded to the base material. In an aspect the plurality of joints are secured to the base material by spot welding. In an aspect the plurality of joints comprise spot welds, joining the sheet to the underlying base material. In an aspect the spot welds are removable. In an aspect the sheet includes a combination of at least two structures. For instance, the sheet may include folds as the joints at one or more of the plurality of joint locations, and at least one of folds, ribs, and bi-facial curves in the free-standing sheet spanning between joint locations. Furthermore, the sheet may include folds along edges of the sheet.

In an implementation a process chamber is provided. The process chamber may include walls, base, and cover defining a process chamber cavity; within the process chamber cavity, a pedestal and heater for supporting a substrate to receive a deposition material; a coating secured to at least one interior surface of the process chamber, the coating comprising: at least one sheet for receiving excess material, the at least one sheet structured to provide at least one of stress relief and defect prevention and a plurality of joints securing the at least one sheet at joint locations to the at least one interior surface. In an aspect the at least one interior surface comprises a shielding component within the process chamber cavity located to shield an interior surface of the process chamber from the excess material.

In an implementation a method is provided for coating a process chamber component. The method may include providing a coating for protecting the process chamber component from excess material, the coating comprising at least one sheet for receiving excess material, the at least one sheet structure to provide at least one of stress relief and defect prevention, and a plurality of joints for securing the at least one sheet at joint locations to the process chamber component; and bonding the coating by conforming the coating to a surface of the process chamber component intended to be protected, and spot welding the plurality of joints to the process chamber component.

Other aspects and advantages will become apparent from the following description.

### BRIEF DESCRIPTION OR THE DRAWINGS

Embodiments will now be described with reference to the appended drawings in which:

FIG. 1 is aside cross-section view of an exemplar prior art process chamber.

FIG. 2 is an exemplar plot of defect probability over time.

FIG. 3 is a side cross-section view of the process chamber of FIG. 1, further including an embodiment of a shield coating.

FIG. 4 is a side section view of an embodiment of a coating.

FIG. 5A is a side section view of an embodiment of a coating.

FIG. 5B is an isometric view of an embodiment of a portion of an annular shielding component covered by a coating.

FIG. 6A is a side section view of an embodiment of a coating.

FIG. 6B is an isometric view of an embodiment of a portion of an annular shielding component covered by a coating.

FIG. 7A is a side section view of an embodiment of a coating.

FIG. 7B is an isometric view of an embodiment of a portion of an annular shielding component covered by a coating.

FIG. 8 is a side section view of an embodiment of a coating covering a portion of a shielding component.

FIG. 9A is a side section view of an embodiment of a hybrid coating.

FIG. 9B is a side section view of an embodiment of a hybrid coating.

FIG. 10 is a side section view of an embodiment of multiple layered coatings.

FIG. 11 is a side section view of an embodiment of a coating.

FIG. 12A is a side section view of an embodiment of a coating.

FIG. 12B is a side section view of an embodiment of a coating.

FIG. 12C is a side section view of an embodiment of a coating.

FIG. 12D is a side section view of an embodiment of a coating.

FIG. 12E is a side section view of an embodiment of a coating.

FIG. 12F is a side section view of an embodiment of a coating.

### DETAILED DESCRIPTION

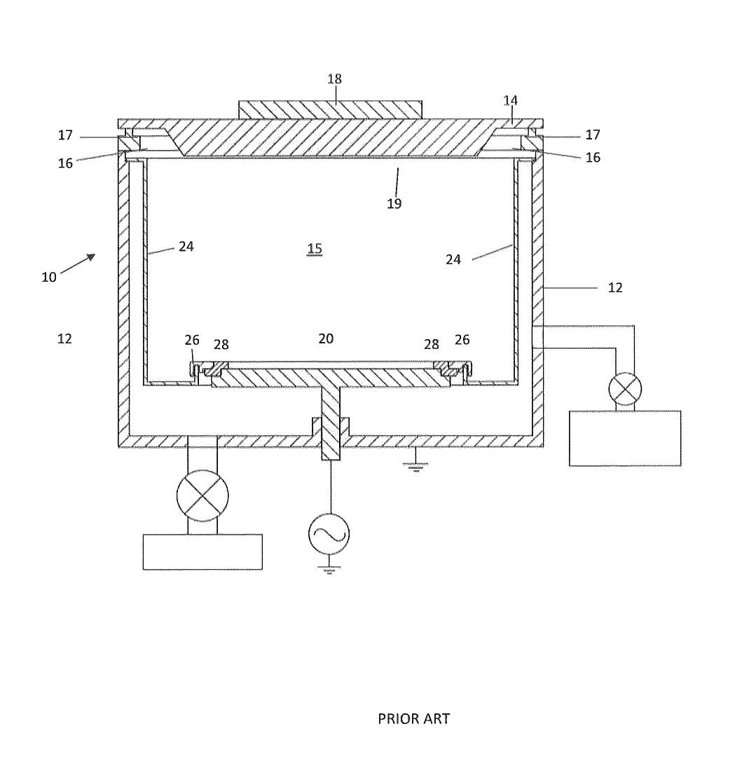

Referring to FIG. 1, a cross-section of an exemplar process chamber 10 is illustrated. The process chamber 10 includes a chamber body defined by chamber walls 12, base 13 and cover 14. The chamber body defines a chamber cavity 15 in which the process is contained. The chamber walls 12 and base 13 are commonly constructed in fixed arrangement to one another with the cover 14 being removable. Typically, a sealing ring 16 and sealing gasket 17 are provided to assist with securing the cover 14 in sealing engagement with the walls 12. A magnet 18 is provided above the cover 14 to work in cooperation with a target 19 located on the inside of the cover 14 to generate material to be deposited on a substrate.

Below the target 19 a pedestal 22 is provided for supporting the wafer 20 to be coated in the process chamber 10. Typically, a heater is located beneath, or within, the pedestal 22 for heating the substrate (wafer 20) and the chamber cavity 15. As illustrated in FIG. 1, shielding components, i.e. process kit components, are provided to shield the walls 12, base 13, and pedestal 22 from deposition of excess material. In the exemplary FIG. 1, the shielding components include an inner shield 24 for shielding the walls 12. The inner shield 24 may further shield the base 13 when working in cooperation with the cover ring 26. A deposition ring 28 further seals edges of the pedestal 20 and the heater 22.

As will be appreciated, the illustrated shielding components are for illustrative purposes only, and other combinations or types of shielding components may be employed for a particular process chamber 10. As described above, the purpose of the shielding components is to block deposition of material onto parts of the process chamber 10. Standard semiconductor process chambers employ shielding components of a variety of materials including metals (such as stainless steel and aluminum), high purity ceramic parts, and quartz parts.

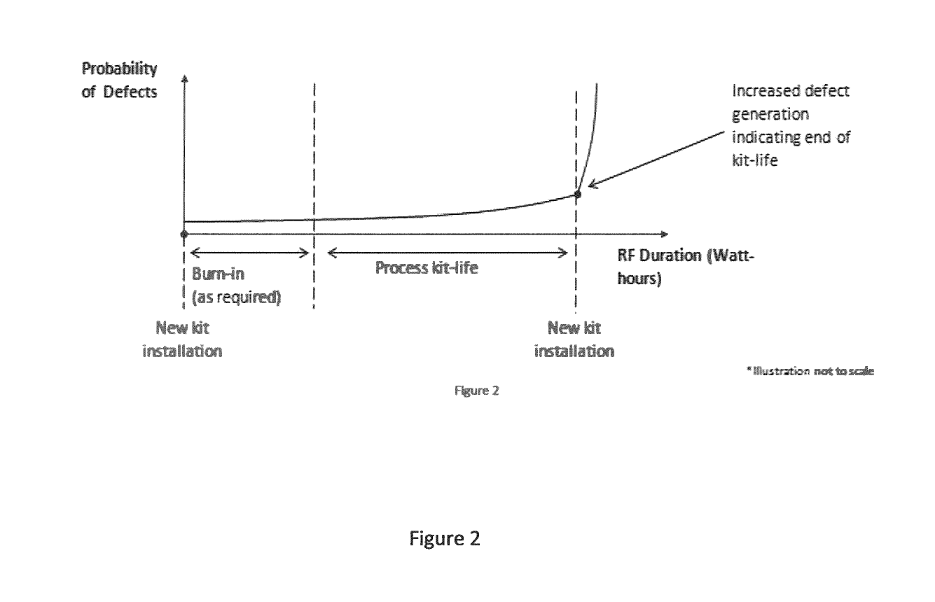

Referring to FIG. 2, an exemplar plot of defect probability over time is presented. FIG. 2 illustrates the basis for assigning an operational life to a process kit. In general, the operational life is defined by the experimentally-determined length of time before which the risk or probability of excess material film flaking causing a process defect rises above a threshold level. In practice, the probability that a defect will occur follows a relatively smooth curve before the probability of a failure begins to increase exponentially. The inflection point is a result of the non-uniform build-up of the excess material resulting in stress concentrations within the excess material film. Process cycling with areas of increased stress concentration leads to weakening in the excess material film at those areas, and finally to flaking. This inflection point in the probability of defect curve generally defines the useful operational life of the process kit. After this inflection point, the risk of a defect quickly rises above the threshold level. Accordingly, the inventors have worked to present a system and method for extending the time before which the probability of defects begins to increase rapidly.

Through experiment and analysis, the inventors have determined that the factors which affect when the excess material film starts to flake include:
Underlying surface shape curvature and asymmetry
Film stress
Film thickness
Coefficient of thermal expansion (CTE) of the film and the underlying material
Film adhesion to the underlying material (surface finish & underlying material geometry)
Film cohesion
Thermal cycling of the process chamber
Pressure cycling of the process chamber

Of these factors, the most important readily addressable factors include differing rates of thermal expansion between the film and the underlying material, and physical stresses in the film resulting from surface shape curvature, film thickness, and thermal expansion of the underlying material.

The inventors have developed a system and method for addressing two types of film failure in particular: adhesive failure and cohesive failure. Adhesive failure results when the film fails to adhere to the underlying material. Cohesive failure results when the film lacks internal cohesion, and pieces of film may break or flake off from the main body of the film. It has been determined that, of the shielding components, flaking tends to be most severe on the deposition ring. It appears that this is predominantly due to i) the temperature gradient created between the heated pedestal and the unheated edge of the deposition ring; and, ii) the likely higher rate of deposition from the deposition ring's close proximate to the substrate. As a result, the inner diameter of the annular deposition ring is subjected to higher temperatures and larger amounts of deposited excess material, than the outer diameter. Furthermore, specific materials tend to more prone to flaking than other materials. For instance, Tungsten (W) tends to flake more often than Titanium (Ti). This can result in adhesive failure between cells and cohesive failure at cell ridges.

Finite Element Analysis (FEA) of shielding components cycling through process operations with the addition of an excess material film has shown a marked difference in the internal stresses within the film as compared with the base material of the shielding component. The base geometry of the shielding component creates an inherent stress in the film as it builds up over time. The process operation cycling exacerbates and increases these stresses as pressure and temperature is cycled during operations. The present system and method provides the flexibility to address the inherent stresses caused by shielding component geometry and variable environmental factors, for temperature gradients caused by proximity to the heater, in the process chamber.

In a first implementation, the inventors have provided a coating comprised of a semi free-standing metal coating for wrapping over the exposed surfaces of base materials, such as the shielding components. The coating is secured to the underlying base material by spaced support joints that bond the coating to the underlying base material at the joint locations, but leave it free to expand, or flex, relative to the base between joint locations. In an aspect, the support joints may be secured by spot welding the coating to the underlying base material. In an aspect, the support joints may be formed from the spot welding, and the coating may be secured to the base material by spot welding the coating to the base material. In an aspect, the support joints may comprise structural features in the coating, the joints secured by spot welding the structural feature to the base material. The coating, secured by the spaced support joints to the relatively fixed underlying material, presents a relatively flexible surface to receive the deposited excess material.

In some implementations, the coating may be removably attached to the base material. The coating may be removably attached by selection of spot welding size and strength to allow for selective removal of the coating after its useful process run life.

During process operations, the coating is able to bend and flex under the process conditions and the excess material film growth. This allows for inherent stress relief, instead of building stress concentrations within the excess material film. In some aspects, the coating may further feature a patterned surface. The patterned surface providing a surface texture to improve the bonding of excess material deposited on the surface of the coating. In some aspects the coating comprises a structure that allows the coating to flex and deform in an “anti-stress” manner to receive the excess material and reduce stresses that may arise at the interface between the coating surface and the excess material film, as well as in the film itself. In some aspects, the coating may be structured to provide stress relief to the excess material film in a specific direction. For instance, the shielding component may have a predominantly directional stress that is imparted to the excess material film due to the geometry of the shielding component and/or environmental factors such as temperature gradient within the process chamber. In this aspect, the coating may be structured to include folds or coating curvature that allows for elastic expansion and contraction of the coating in a specific direction. In some aspects, the coating may be structured to reduce crack propagation and stress concentration in the excess material film. In some aspects, the coating may be structured, for instance through coating curvature, to allow for elastic expansion and contraction in any planar direction of the coating.

In some aspects the coating includes both an anti-stress structure to provide stress relief in a deposited excess material film and a patterned surface to improve the bonding of the excess material to the coating. The coating protecting an underlying material once it has been secured to the underlying material at one or more joint locations. In some cases, the joints may be formed as spot welds. In some cases, the joints may be formed as structural features of the coating that may be spot welded to the underlying material. The coating may further be removable from the underlying material.

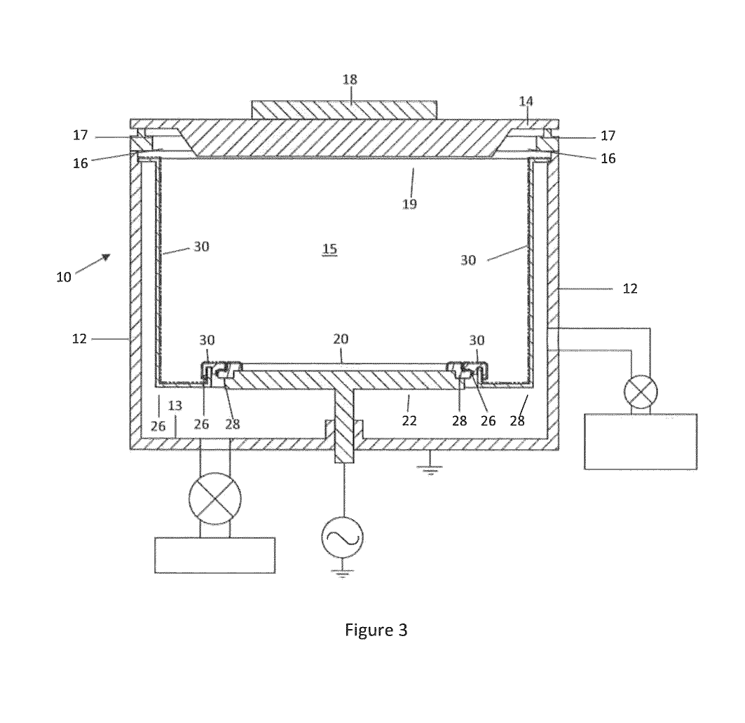

Referring to FIG. 3, the process chamber 10 is illustrated with the addition of a coating 30 over select shielding components. The coating 30 may be applied to the surface of any base material within the process chamber 10 that may be exposed to excess material. In the illustration of FIG. 3, the coating 30 is applied to shielding components, such as process kit components, including the inner shield 24, the cover ring 26 and the deposition ring 28. In embodiments where other portions of the process chamber are exposed, the coating 30 may be applied to the exposed portions of the process chamber as the base material. As will be appreciated, these are the parts of the process chamber 10 that typically receive the bulk of the excess material, but other parts of the chamber may usefully be covered by the coating 30.

The coating 30 may be produced from a suitable sheet, such as a metal sheet (for instance: Al, Ti/TiN, Ta/TaN, Cu, Ni, Cr, Zn, SST, Alloys, Alumina (Al2O3), Aluminum nitride (AlN), Yttira (Y203), Alumina-Titania (Al203/TiO2), Yittira-Alumina (Y203/Al03)), which are standard materials used for constructing process chambers. The sheet may have a varying thickness depending on a shape and configuration of the component to be covered but typically will be between 30 μm to 10 mm thick.

The coating 30 acts to separate the excess material film from adhering to the underlying shielding component. The thickness and material type of the coating 30 are selected to allow for deformation, expansion, contraction, flexion, or compression, to accommodate differences between expansion of the underlying shielding component and expansion in the excess material film. This allows for film stresses to be distributed, reducing overall film stress and reducing stress concentrations.

In the current solution for employing shielding components, that lacks the coating 30, the excess material bonds directly to the surface of the shielding component. The underlying shape of the shielding component, along with the differing material expansions cause increasing stress to be stored in the excess material film as its thickness builds up. Use of the coating 30, by comparison, separates and isolates the excess material film (e.g. W—Ti) from the shielding component (e.g. Aluminum or stainless steel). By isolating the excess material film from the shielding component the excess material film is relieved from accommodating the greater thermal expansion (e.g. ˜4× larger for stainless steel) of the underlying material as temperatures increase.

The composition (i.e. material selection) and thickness of the coating 30 may be selected based upon an intended process run of the process chamber 10, and in particular the intended operating temperature of the process chamber 10. The selection considers the temperature range of the process chamber 10, as well as the material make-up and thermal expansion properties of the process chamber 10, shielding components, and excess material that will be deposited during the process. The selection is to minimize the initial risk that the sheet material would fail during the first few hours of deposition. The coating 30 should maintain its structural integrity during the initial run-in period to minimize any shape instability which may lead to a growth in defect generation as the excess material layer builds up over time. After this run-in period, the material properties of the sheet are largely dominated by those of the excess material (e.g. W—Ti).

As mentioned above, the coating 30 may include an anti-stress structure. The anti-stress structure being one or more structural features that provide different properties from the initial flat sheet of base material. The anti-stress structure may be included to address the following items:
Reduction in defect (crack) propagation by providing a surface profile that reduces straight paths between any two adjacent points
Locating areas where the coating is able to elastically deform, as a transition from areas that plastically deform to distribute stress and reduce stress concentrations
Counteracting the compressive effects of excess material deposition
Accommodate fixed joint locations, especially where the underlying material surface includes directional changes

The anti-stress structure may also be influenced by process conditions such as temperature. Based on the operating temperature, and the selected sheet material of choice, the structure of the coating may be selected to improve thermal contact with the underlying shielding component to improve heat transfer. The improved thermal contact may be provided, for instance, by selecting joint location spacing and contact area to control the heat flux from the coating 30 to the underlying shielding component. Control of the heat flux between the coating 30 and the shielding component can be used to further reduce stresses in the excess material film.

For instance, during process start-up the heater in the pedestal 22 provides a localized heat source, which leads to a temperature gradient which falls off from the center of the process chamber 10, where the pedestal 22 is located, to the periphery of the process chamber 10. The shielding components, especially the cover ring 26 and deposition ring 28, will have a similar temperature gradient, with a higher temperature at their inner edge than their outer edge. Excess material deposited on such a shielding component will be subjected to: a) different temperatures at different deposition locations; and, b) different underlying material expansion magnitudes as the process chamber is cycled. By controlling the heat flux between the coating 30 and the underlying shielding component, a deposition surface may be presented that has a more uniform, i.e. less extreme, temperature gradient.

In design, a FEA of the shielding component may be conducted to evaluate the expected transient heat transfer and temperature gradients for that shielding component under selected process conditions (thermal cycling, excess material composition, excess material deposition rate, pressure cycling, etc.). The goal is to identify any non-uniform or non-symmetric thermal expansion conditions and any non-uniform, non-symmetric, or extreme temperature gradient conditions in that shielding component. As a point of interest, it is useful to identify, if any, critical periods within the thermal cycling of the process where the shielding component exhibits extremes in expansion, contraction, or internal stress. The material behaviour during those critical periods, e.g. expansion, contraction, and direction, can be used to identify key stress conditions that need to be accommodated.

Accordingly, based on shielding component geometry and the rate and magnitude of thermal cycling for an intended process, a detailed optimization can be employed to select an anti-stress structure for a coating 30 that compensates for the non-uniformity in temperature gradient, thermal cycling, process kit geometry, excess material composition, excess material deposition rate, and designed excess material film thickness during the operational life of the coating 30. In general, once an anti-stress structure, joint locations, joint size, and joint type have been selected, a review FEA should be conducted on the combination of the shielding component and a coating 30 including the selected features. The review FEA is focussed on two aspects: i) behaviour of the shielding component with the addition of the coating 30; and, ii) behaviour of the coating and identification of any non-uniform or non-symmetric thermal expansion conditions and any non-uniform, non-symmetric, or extreme temperature gradients conditions in the coating 30. The joint locations need to be considered as locations of plastic deformation, that may require accommodation with additional elastic deformation in their vicinity.

Accordingly, in an implementation a coating 30 may be designed as a sheet with a an anti-stress structure for an identified shielding component and expected process conditions. The structure may be imparted into sheet material by rolling, embossing, pressing, folding, or otherwise working the sheet material as may be required to impart the required structure. The structured sheet is then wrapped around the base material and bonded (welding, etc) at selected locations to form secure joints that hold the sheet in place.

In an implementation the coating 30 may be designed from a sheet with some elements of the structure forming part of the joints, such as a fold, to be bonded to the base material. In some aspects, the base material comprises a shielding component. In some aspects, the base material comprises a portion of the process chamber. In some aspects, the base material comprises a lower coating layer.

During process conditions, the high temperature deposition process will cause the resulting excess material film to expand freely except at the joints and to allow for a more natural film stress to develop over the coating 30. The free-standing sheet portion of the coating 30 may deform into a convex or concave shape depending on the nature of the deposition, temperature, as well as the sheet structure. This deformation relieves stress conditions that would otherwise be stored within the excess material film. As a result, the risk of a catastrophic flaking event is reduced.

From their research and analysis, the inventors have identified a list of concepts and items to focus on during the design and analysis of the coating 30. The most severe conditions in the coating 30 to be addressed include joint failure and edge defect propagation. Joints tend to fail as they are fixed locations at the boundary between the underlying shielding component and the deposition surface of the coating 30. These locations tend to exhibit plastic deformation as the base of each joint is fixed in relation to the underlying shielding component. Defects, i.e. cracks, tend to be most problematic at the edges of the sheet, or extremes in curvature or corners in the underlying shielding component.

The inventors have determined that a robust coating 30 typically includes some or all of the following features:
Dense, rigid, boundary joints at the sheet edges
   Rigid boundary joints limit the outward expansion of the sheet at the edges and prevents potential buildup of edge defects.
Optimize the free-standing sheet length (the unsupported area between two joints in the radial direction for an annular component) by balancing the thermal heat transfer-joint stress-material yield strength, to result in a suitable convex or concave deformation in the Z-direction (perpendicular to the surface of the shielding component)
   Allowing for the free-standing sheet portions of the covering 30 to assume a convex or concave deformation relieves stresses resulting from expansion/contraction of the underlying shielding component.
   For a given sheet and joint material, the material yield strength is a constant. The thermal heat transfer is a function of the sheet material CTE, joint material CTE, shielding component CTE, area of contact at the interface locations and cross-sectional area of the joints. The joint stresses may be calculated using FEA based on differing expansion magnitudes and rates of the joint, sheet, and shielding component as well as the structures and composition of these components.
   In design the shielding component and the sheet of the covering 30 may be held as constants while the joint position, spacing, number, size, and shapes may be varied until an acceptable concave/convex curvature in the free-standing sheet portion of the covering 30 is achieved.
Utilize concentricity, and the symmetry of the shielding components and process conditions, in designing the coating 30 (particularly the anti-stress structure)
   The deposition process is uniform concentrically, and environmental conditions tend to predominantly vary radially.
   The main analysis is radially across the annular shielding components through the joint locations.
   The secondary analysis is radially across the annular shielding components avoiding the joint locations.
Select sheet structures that minimize the probability of crack propagation for a given geometry and stress profile
   The two principle forms of crack propagation to be avoided are straight line crack propagation through the body of the sheet and crack propagation at the edges of the sheet.
   Optimize the profile of the sheet structural features (i.e. height & spacing of features) based on material properties (likely maximum deformation determined by FEA review), manufacturability, and excess material composition.
Locate folded edges in the sheet to round-off the coating boundary to provide additional resistance to defect generation (i.e. crack propagation) at the sheet edges

In some embodiments the anti-stress structure may be composed of two or more different structural features and/or feature sizes. In general, where a plurality of structural features and/or feature sizes are employed, the texturing may be varied at locations of differing stress profiles. For instance, a first structure may be employed proximate to joint location, a second structure may be employed in the body of the free-standing sheet, and/or a third structure may be provided at one or more of the covering boundaries.

The use of a plurality of structural features and/or features sizes provides a coating 30 with different properties at different locations of the shielding component. For instance, at each location of the shielding component, depending upon particular process conditions the highest stress buildup might arise from any of rapid heating (thermal expansion) OR rapid cooling (thermal contraction) OR the inherent asymmetry in the underlying shielding component, covering boundary, and/or joint placement.

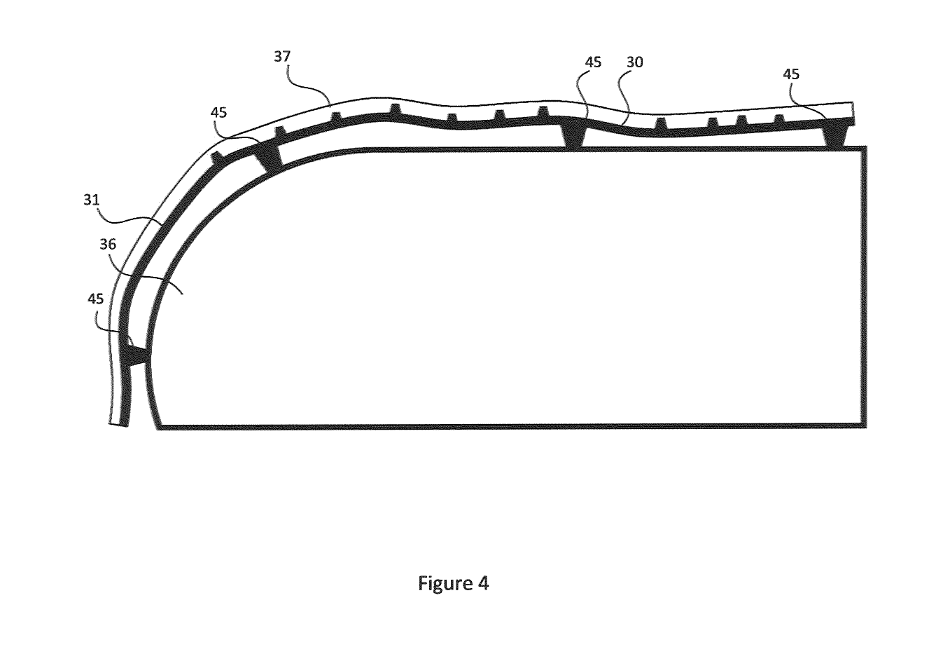

Referring to FIG. 4, in a first aspect, the coating 30 may be secured to the shielding 36 component at joint locations 45 by spot welding, presenting an exposed surface of the sheet portion of the coating 30 as a deposition surface 31 for receiving the deposited film 37 of excess material. The coating 30 may further comprise a texturing of the deposition surface 31 to provide improved adhesion of the deposited film 37, and to reduce stress in the deposited film 37 which might arise due to environmental or physical factors within the process chamber.

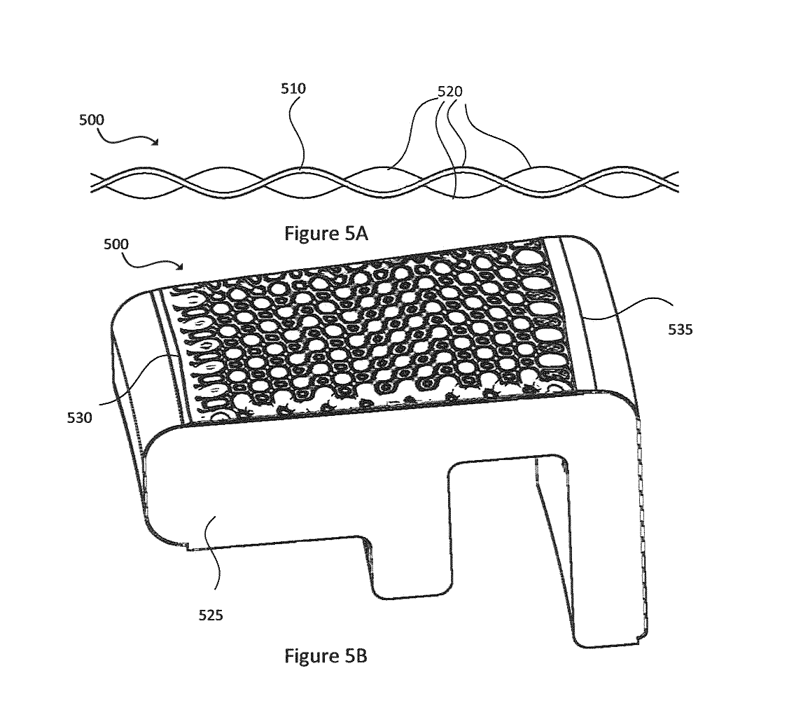

FIGS. 5A and 5B illustrate an embodiment of an anti-stress structure in the sheet of a coating 500 that provides non-directional stress relief. Referring to FIG. 5A, a side section view of an exemplar coating 500 is illustrated. The coating 500 includes bi-facial curves 520 in the sheet 510 of the coating 500. The curves 520 may be uniform, or may differ in height or width, typically near fixation points such as edge boundaries or joint locations. The use of bi-facial curves 520 ensures that the shortest path between any two points on the sheet is never a straight line (always curved). This structure assists to slow down/prevent crack propagation through the sheet. Bi-facial curves 520 may be considered to be an incremental improvement that generally prevents crack propagation. Since the structure is non-directional, it does not address specific geometries or process conditions. The pattern may be optimised by selecting the height and width of the curves which affect the physical performance of the patterned sheet.

Referring to FIG. 5B the coating 500 of FIG. 5A is illustrated in place on a segment of an annular shielding component 525. The inner boundary 530 and outer boundary 535 are illustrated as folds in the sheet that are affixed to the surface of the annular shielding component 525. The illustrated annular shielding component 525 is intended to work in cooperation with another adjacent part which will interface at or near the inner boundary 530.

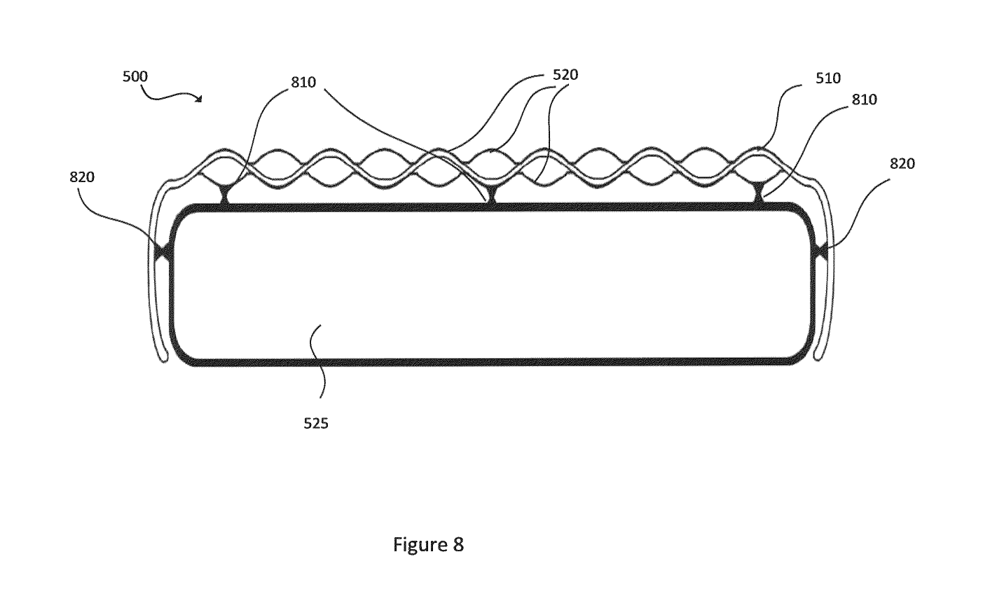

Referring to FIG. 8, a side section view of the coating 500 is illustrated. The edge joints 820 and joints 810 that secure the sheet portion of the coating 500 to the shielding component 525 are illustrated.

FIGS. 6A and 6B illustrate an embodiment of an anti-stress pattern in the sheet of the coating 30 that provides directional stress relief. Referring to FIG. 6A, a side section view of an exemplar coating 600 is illustrated. The coating 600 is waved with a series of ribs 620 in the sheet 610 of the coating 600. The ribs 620 may be uniform, or may differ in height or width, typically radially across the underlying shielding component. The use of ribs 620 provides for a spring-like underlayment to receive the excess material. The ribs 620 may be employed where the underlying stress condition is directional, typically in a radial direction, as a result of the geometry, process, or other conditions. Since the texture is directional, it may be employed responsive to specific geometries or process conditions. As indicated above, the structure may be optimised by selecting the height and width of the ribs 620 which affect the physical performance of the structured sheet.

Referring to FIG. 6B the coating 600 of FIG. 6A is illustrated in place on a segment of an annular shielding component 525. The inner boundary 630 and outer boundary 635 are illustrated as folds in the sheet that are affixed to the surface of the annular shielding component 525. The illustrated annular shielding component 525 is intended to work in cooperation with another adjacent part which will interface at or near the inner boundary 630.

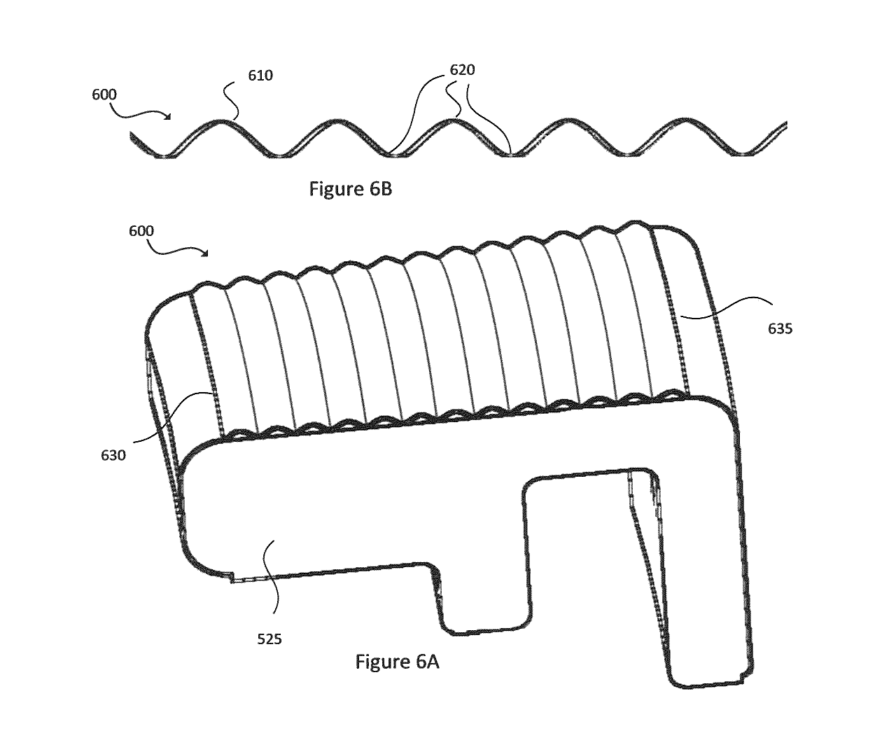

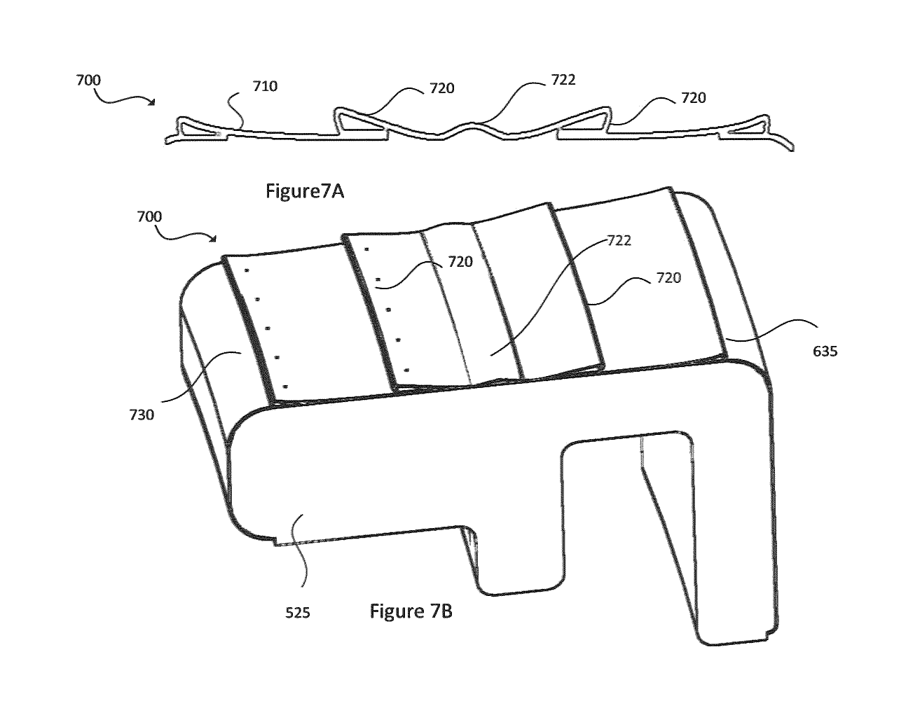

FIGS. 7A and 7B illustrate an embodiment of an anti-stress structure in the sheet of the coating 30 that provides directional stress relief. Referring to FIG. 7A, a side section view of an exemplar coating 700 is illustrated. The coating 600 is waved with a series of folds 720 722 in the sheet 710 of the coating 700. The folds 720 722 may be uniform, may differ in height or width, or may differ in structure as illustrated in FIGS. 7A and 7B with joint folds 720 and free-sheet folds 722. The use of folds 720 provides for increased surface contact with the underlying shielding component for increased heat transfer to reduce sheet temperatures while still retaining spring-like deformation. The joint folds 720 may also provide for increased strength and rigidity in the covering 700. This may be useful, for instance, at boundary edges. The folds 720 722 may be employed where the underlying stress condition is directional, typically in a radial direction, as a result of the geometry, process, or other conditions, and to control the temperature gradient in the sheet. Since the texture is directional, it may be employed responsive to specific geometries or process conditions. As indicated above, the structure may be optimised by selecting the height and width of the folds 720 722 which affect the physical performance of the structured sheet.

Referring to FIG. 7B the coating 700 of FIG. 7A is illustrated in place on a segment of an annular shielding component 525. The inner boundary 730 and outer boundary 735 are illustrated as folds in the sheet that are affixed to the surface of the annular shielding component 525. The illustrated annular shielding component 525 is intended to work in cooperation with another adjacent part which will interface at or near the inner boundary 730.

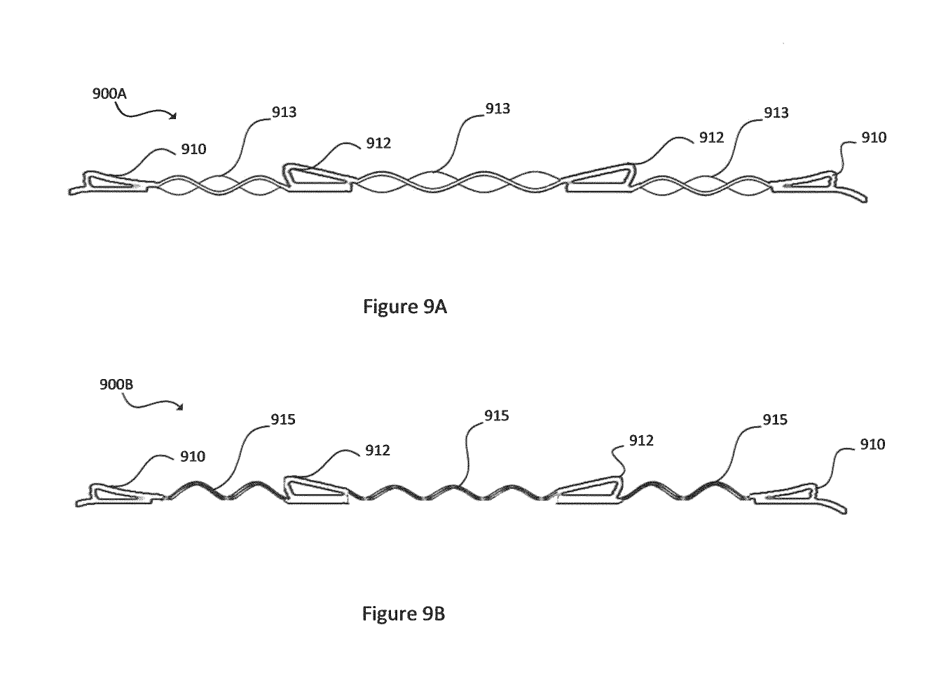

Referring to FIGS. 9A and 9B, section views of coatings 900A 900B each composed of hybrid structures are illustrated. In the hybrid structures, the joints 910 912 may be provided as folds, while the free-standing sheet may be provided as another structure. In the example of FIG. 9A, the free-standing sheet 913 is composed of bi-facial curves. In the example of FIG. 9B, the free-standing sheet 915 is composed of ribs. The use of a hybrid structure allows for flexibility in coating design. For instance, edge joints 910 and feature joints 912 may be provided using the folds to increase surface contact with the underlying shielding component. The free-standing sheet 913 915 may be structured to provide non-directional or directional stress relief as may be required for a particular part, or location on a part.

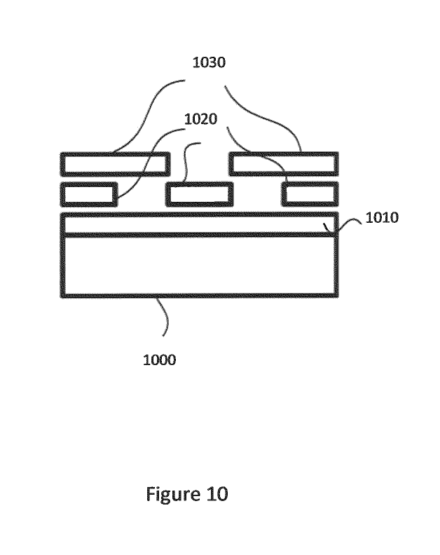

Referring to FIG. 10, a side cross-section view illustrating an implementation where multiple coatings 30 may be applied in layers onto an underlying material. As illustrated, a first coating layer 1010 is bonded to the underlying material 1000. One or more additional coating layers may be bonded to the first coating layer 1010 to collectively provide a second coating layer 1020. Similarly, one or more additional coating layers may be bonded to some or all of the second coating layer to provide a third coating layer 1030. The joints connecting the layers are not visible in FIG. 10, but spot welds connecting the sheet, or structures of the sheet, may similarly be used to bond layers to layer. The use of multiple coating layers provides more flexibility in accommodating inherent stresses that may be present in certain base material geometries. For instance, layers may overlap when conforming to curves or steps in the underlying material. A second coating layer 1020 may be used on top of a first coating layer 1010 at a union between sections of sheet. The second coating layer 1020 may transition to become a first coating layer 1010 as it extends from the union.

As indicated above, in an aspect, the present anti-stress coating may also be removable. In an additional aspect, the present anti-stress coating may also comprise a deposition layer patterned to provide improved adhesive bonding with the deposited excess material film.

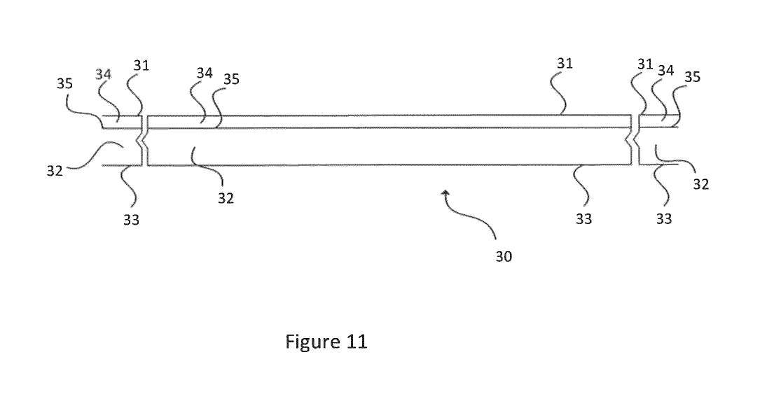

Referring to FIG. 11, in an aspect the coating 30 may further comprise a deposition layer 34 bonded to the sheet surface 35. The deposition layer 34 typically comprising a metal deposition onto the sheet surface 35, to improve retention and capture of excess material (for instance: Al, Ti, Ta, Cu, Ni, Cr, Zn, SST, and Alloys). In some aspects, the coating may be comprised of a common material for each of the sheet 32 and the deposition layer 34.

The purpose of the deposition layer 34 is to provide a deposition surface 31 that is more receptive to receiving excess material than the sheet surface 35. The deposition layer 34 is fully bonded to the sheet 32, and of reduced thickness, typically ranging between 5 nm to 1000 μm. The deposition layer 34 may be produced, for instance, by anodizing, plasma coating, or spray coating the sheet 32 with the coating material. In some aspects, the deposition layer 34 may comprise a same material as the sheet 32. In some aspects, the deposition layer 34 may comprise a different material as the sheet 32. The deposition layer 34 provides for improved bonding with excess material over the sheet 32 alone, as it has been found that coating the sheet 32 with a deposition layer 34 provides for improved bonding of excess material over the sheet 32 alone.

Accordingly, a coating 30 may be selected for improved bonding characteristics for a given set of process conditions, e.g. excess material, without changing the composition of the underlying component to be protected. Furthermore, a plurality of coatings 30, each presenting a different deposition surface 31 may be provided to a manufacturing location. An appropriate coating 30 may be applied to shielding components for a specific process chamber run. Provision of coatings 30 having different deposition surfaces 31 allows for matching of a particular deposition surface 31 to a specific process chamber operational cycle, while using shielding components of a same composition.

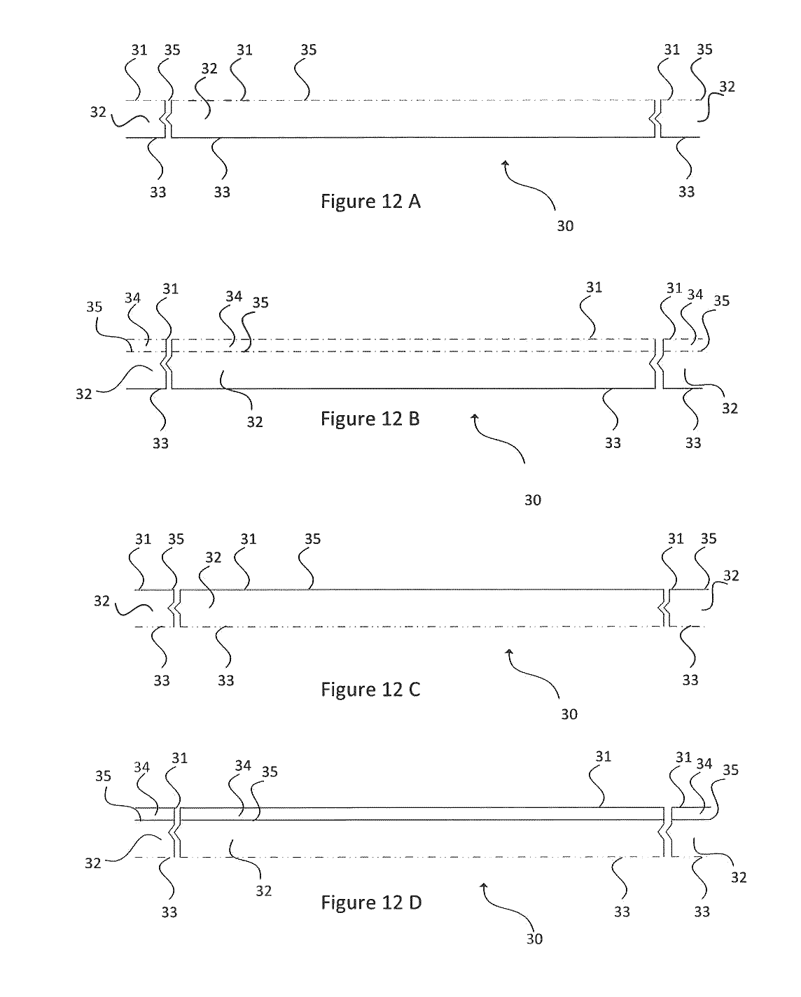

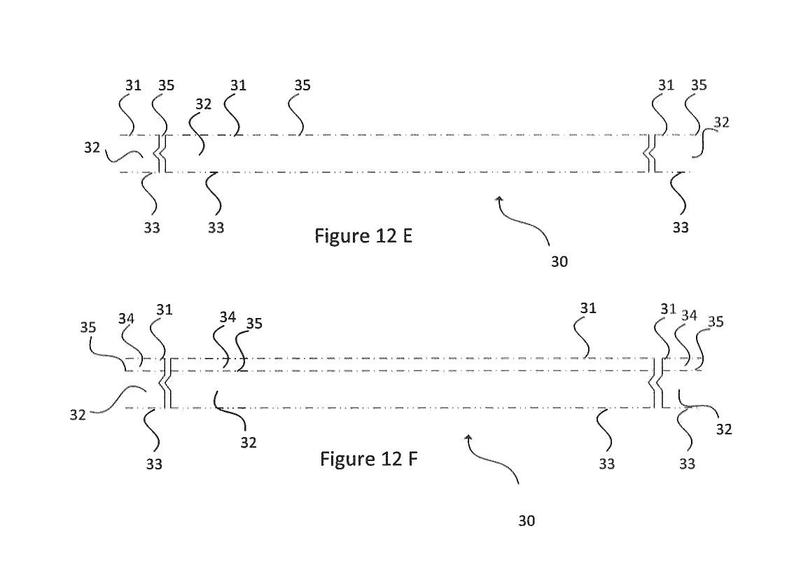

Referring to FIG. 12A, in an aspect the coating 30 may further comprise a treatment or preparation applied to the deposition surface 31 to impart a deposition texture or desired surface roughness into the deposition surface 31. In the example of FIG. 4A, sheet surface 35 is treated to provide improved bonding for reception and retention of the excess material. The treatment may comprise, for instance, a treatment to provide a deposition texture exhibiting an increase in a roughness of the sheet surface 35 such as by bead blasting, etching, machining, or other means. In other aspects, where the coating 30 is ductile, the treatment may comprise a mechanical treatment applied to the sheet 32 to deform the sheet surface 35, for instance by rolling or pressing the sheet 32 with a patterned roller or press having a raised profile, to impress a pattern or irregular surface into the deposition surface 31 as the deposition texture.

Referring to FIG. 12B, the coating 30 comprises the sheet 32 and the deposition layer 34, with a treatment applied to the deposition surface 31 of the deposition layer 34. Depending upon the treatment applied, and the thickness of the deposition layer 34, the treatment may further deform the sheet surface 35, though it is not the deposition surface 31 in this embodiment. For example, where the sheet 32 and the deposition layer 34 are passed through a roller, one of the rollers may include a textured surface to impress a texture onto the deposition surface 31. Where the textured surface is of sufficient profile, both the deposition layer 34 and the sheet surface 35 of the sheet 32 may both be deformed to accommodate the profile.

Referring to FIGS. 12C and 12D, in an aspect a similar treatment may be applied to the bonding surface 33 of the sheet 32 to impart a bonding texture in the bonding surface 33. In this case the treatment may be intended to provide reduced contact area between the bonding surface 33 and the shielding component. The reduced contact area may be useful, for instance, to provide a lower bonding force between the coating 30 and the component. The reduced contact area may also be useful to assist with temperature maintenance in the process chamber cavity 15 by providing a lower heat transfer rate between the coating 30 and the shielding component. In this fashion, the coating 30 may provide a measure of insulation to reduce a rate of heat transfer out of the process chamber cavity 15. For some processes the dynamics prefer a relatively slower heat transfer rate out of the process chamber cavity 15. For these processes, a coating 30 may be selected for both a material property to reduce heat transfer and/or a reduced coating contact area to reduce the contact between the coating 30 and an underlying shielding component. In cases where a relatively higher heat transfer rate is preferred, the bonding surface 33 may be relatively smooth, providing a relatively higher heat transfer rate.

The treatment may similarly comprise, for instance, a treatment to provide a bonding texture exhibiting an increase in a roughness of the bonding surface 33 such as by bead blasting, etching, or other means. In other aspects, the treatment may comprise a mechanical treatment applied to the sheet 32 to deform the bonding surface 33, for instance by rolling or pressing the sheet 32 with a patterned roller or press having a raised profile, to impress a pattern or irregular surface into the bonding surface 33 as the bonding texture. The bonding texture selected to affect at least one of a bonding between the bonding surface 33 and the shielding component to receive the coating, and a heat transfer rate between the coating 30 and the shielding component.

Referring to FIGS. 12E and 12F, in an aspect a treatment may be applied to both the deposition surface 31 (and potentially the sheet surface 35), and the bonding surface 33. In this aspect, the treatment may comprise a same treatment applied to both of the opposed surfaces of the coating 30. In this aspect, the treating may alternately comprise a different treatment applied to both of the opposed surfaces of the coating.

According to another aspect of the invention, there is provided a process kit component comprising a base dimensioned to be positioned within a semiconductor process chamber with respect to an intended deposition substrate; and a coating 30 for shielding the base, the sheet comprising a metal sheet layer conforming to at least a portion of the base; and a coating layer affixed to and conforming to the metal sheet, the coating having a enhanced bonding strength between metal sheet layer and deposition material there across, wherein the coating 30 is selectively removable from the base.

Because the coating 30 is conformable, it can be selectively conformed to various shapes and configurations of an underlying shielding component. The coating 30 providing a deposition surface 31 receptive to excess material that can be relied upon to uniformly receive and “hold” the excess material, and the resultant deposition film build-up without immediate flaking of the film. Furthermore, a coated shielding component may be cleaned by simply removing and discarding the coating 30. A fresh coating 30 may be applied, providing a fresh deposition surface 31 for receiving excess material. Furthermore, the make-up of the deposition surface 31 may be tailored to a particular process. For instance, a process chamber running a copper process (i.e. using a copper target) can be shielded by a coating having a copper deposition surface 31. Conveniently, while a soft copper deposition surface 31 may be receptive to capturing copper excess material, the shielding components may be formed from another material, such as steel or titanium for durability. As compared with prior art methods for cleaning a process kit component whose actual surface is deposition surface that receives surface treatment by bead blasting or aluminum arc spraying, simply encapsulating the shielding component or a portion thereof, with a replacement coating 30 takes far less time to complete. As such, the coated shielding component can be quickly cleaned and put back into service. Furthermore, the coating 30 may optionally be applied to structural components of the process chamber 10 that may be partially exposed to excess material and require cleaning from time to time.

As explained above, a coating 30 may be provided with a deposition surface 31 matched to an intended excess material. Accordingly, in the case of a removable coating 30, a replacement coating 30 may have a similar roughness as the removable coating 30 it is replacing, or may have a different roughness depending on the type and thickness of an intended excess material. Various replacement removable coatings 30 may be made available in order to provide a selection of roughness levels for use in various stages of deposition where higher or lower stress excess material deposition films are being deposited. In embodiments where the deposition surface 31 comprises a treated surface, the extent of the roughness of a particular removable coating 30 can be tightly controlled, particularly where a mechanical process such as rolling or pressing is employed.

The coating 30 can be applied to any of the exposed surfaces within a process chamber 10. Shielding components comprising ceramic process kit components are typically manufactured with near-mirror smoothness surfaces.

In an aspect, a removable coating for protecting process chamber components from excess material is provided. The removable coating may include a sheet. A bonding surface of the sheet for bonding to a process chamber component and a deposition surface of the coating selected to receive the excess material. In an aspect, the coating may further include a deposition layer bonded to a surface of the sheet in opposition to the bonding surface, and providing the deposition surface. The deposition layer may be formed, for instance, by anodizing, plasma coating, or spray coating material onto the sheet. In an implementation, the deposition surface may be treated to impart a deposition texture into the deposition surface for improving the reception and retention of the excess material on the deposition surface.

In an implementation of the removable coating the sheet may be structured to provide at least one of stress relief and defect prevention. In an aspect, the sheet structure may comprise at least one of folds; ribs; and, bi-facial curves. In an aspect, the structured sheet may include folds as joints to be secured to the underlying base material, such as a process chamber shielding component. For instance, the folds may be spot welded to the underlying base material to secure the removable coating in place on the shielding component.

In an aspect of the removable coating, the bonding surface is treated to provide a bonding texture in the bonding surface for reducing a contact area between the sheet and the process chamber component during bonding. The reduced contact area may reduce a bonding strength between the coating and the process chamber component. The reduced contact area may provide for a lower heat transfer rate between the coating and the process chamber component.

In an aspect of the removable coating, the coating may further comprise a deposition layer bonded to a sheet surface in opposition to the bonding surface. The deposition layer providing the deposition surface for receiving the excess material. The deposition surface may comprise a deposition texture impressed into the deposition layer to present a receptive surface for receiving and retaining the excess material.

In an aspect of the removable coating, the bonding surface may be treated to impart a bonding texture into the bonding surface. The bonding texture reducing a contact area between the sheet and the process chamber component across the releasable bond.

In an aspect, the treatment may comprise rolling or pressing the coating to impress the deposition texture into the deposition surface. In an aspect, the treatment may comprise rolling or pressing the coating to impress the bonding texture into the bonding surface. In an aspect, the bonding treatment applied to the bonding surface is the same as the treatment applied to the deposition surface. In an aspect a different treatment is applied to each of the bonding surface and the deposition surface.

In an implementation of the removable coating the sheet is between 30 μm to 10 mm thick, and the deposition layer is between 5 nm to 1000 μm. In an implementation the sheet and the deposition layer comprise a same material. In an implementation the sheet and the deposition layer may comprise a different material. In an aspect, the deposition layer comprises a metal.

In an aspect a process chamber is provided. The process chamber having walls, a base, and a cover defining a process chamber cavity. The process chamber cavity includes a pedestal and heater for supporting a substrate (e.g. a wafer) to receive a deposition material. The process chamber may further include at least one shielding component located to shield an interior wall surface of the process chamber from excess material resulting from deposition of the deposition material onto the substrate. The process chamber further includes a removable coating releasably bonded to at least one interior surface of the process chamber. The removable coating adapted to receive and retain excess material of the deposition material resulting from operation of the process chamber, and adapted to be removed from the at least one interior surface by breaking the releaseable bond between the removable coating and the at least one interior surface. In an aspect, the removable coating is releasably bonded to the at least one shielding component. In an aspect, the removable coating is releasably bonded to an interior wall of the process chamber.

In an aspect of the process chamber, the removable coating may comprise a sheet having a bonding surface for releasably bonding to the at least one interior surface. In an aspect, the removable coating may further comprise a deposition surface on a sheet surface of the sheet in opposition to the bonding surface. In an aspect, the deposition surface may comprise an exposed surface of a film bonded to the sheet surface of the sheet, the exposed surface of the film providing the deposition surface selected to receive the excess material. In an aspect the deposition surface may comprise a treated surface, for instance by machining, pressing, or chemical etching, the treated surface adapted to receive and retain the excess material.

A method for coating a process chamber component comprising providing a removable coating for protecting the process chamber component from excess material. The removable coating comprising a sheet, a bonding surface of the sheet for bonding to a process chamber component. The coating may further comprise a deposition surface selected to receive the excess material. The method may further comprise bonding the removable coating by conforming the removable coating to a surface of the process chamber component intended to be protected, and spot welding the removable coating to the process chamber component.

In an aspect, a method is provided for cleaning a process chamber component coated with an excess material after completing an operational cycle within a process chamber. The method comprising removing a removable coating releasably bonded to the process chamber component, the removable coating having captured the excess material and, bonding a replacement removable coating to the process chamber component by conforming the replacement removable coating to a surface of the process chamber component intended to be protected, and spot welding the replacement removable coating to the process chamber component.

In an aspect of the method, the deposition surface of the replacement removable coating comprises a different material from the removed removable coating. In an aspect of the method, before the bonding of the replacement removable coating to the process chamber component, the method further comprises treating at least one of the bonding surface and the deposition surface to a surface treatment intended to either improve a bonding of the bonding surface to the process chamber component or to improve the capture and retention of excess material on the deposition surface.

In an aspect the treating comprises bead blasting or arc spraying the deposition surface of the removable coating and/or the replacement removable coating. In an aspect the treating comprises passing the coating through a roller or a press to impress one of a pattern or an irregular surface. In an aspect, the treating comprises treating both the bonding surface and the deposition surface of the coating. In an aspect the treating comprises machining the deposition surface of the removable coating and/or the replacement removable coating.

According to another aspect of the invention, there is provided a process kit component comprising a base dimensioned to be positioned within a semiconductor process chamber with respect to an intended deposition substrate; and a removable coating for shielding the base, the removable coating comprising a metal sheet layer conforming to at least a portion of the base; and a coating layer affixed to and conforming to the metal sheet, the coating having a enhanced bonding strength between metal sheet layer and deposition material there across, wherein the removable coating is selectively removable from the base.

In an aspect, the coating layer having a treated deposition surface that preferentially receives and “holds” excess material in the form of ejected atoms and the resultant excess material film build-up without immediate flaking of the film. This can result in significant defect reduction, and also enables an operator to increase the time between cleanings as compared with smoother process kit component surfaces. During cleanings, the removable coating may be removed, discarded and entirely replaced by a replacement removable coating of the same or similar nature. As compared with cleaning of a process kit component whose actual surface is the recipient of treatment by bead blasting or aluminum arc spraying, or with the re-application of such surface treatment, simply encapsulating the process kit component or portion thereof with a replacement removable coating takes far less time to achieve. As such, the process chamber can be quickly cleaned and put back in service.

A replacement removable coating may have the same amount of generally-uniform roughness as the removable coating it is replacing. Alternatively, such a replacement removable coating may increase or reduce the roughness depending on the thickness of deposition material. Various replacement sheets could be made available in order to provide a selection of roughness levels for use in various stages of deposition where higher or lower stress films are being deposited.

In an embodiment, the removable coating may comprise a ceramic coating. Ceramic process chamber surfaces are preferentially used for higher temperature processes, such as CVD. The ceramic coating may comprise one or more metal weld points embedded in the ceramic and exposed on the bonding surface. The metal weld points of the ceramic removable coating may similarly be spot welded to the process chamber or process component. In an aspect, the deposition surface of the ceramic coating may be treated by machining to obtain a desired surface roughness.

Although embodiments have been described with reference to the drawings, those of skill in the art will appreciate that variations and modifications may be made without departing from the scope and purpose of the invention as defined by the appended claims.

1. A coating for protecting a base material within a process chamber from excess material deposited during operation of the process chamber, comprising:
a sheet for receiving the excess material, the sheet structured to provide at least one of: i) stress relief; and, ii) resistance to crack propagation, in the excess material layer; and,
a plurality of joints for securing the sheet at joint locations to the base material;
wherein the coating sheet is securable to the base material by securing the plurality of joints at the joint locations to the base material.

2. The coating of claim 1, wherein the sheet structure comprises at least one of:
folds;
ribs; and,
bi-facial curves.

3. The coating of claim 1, wherein one or more of the plurality of joints comprise folds in the sheet.

4. The coating of claim 1, wherein the plurality of joints are secured to the base material by spot welding at the joint locations.

5. The coating of claim 4, wherein the spot welds are removable.

6. (canceled)

7. The coating of claim 1, wherein the sheet includes as joints folds at one or more of the plurality of joint locations, and at least one of folds, ribs, and bi-facial curves between the joint locations.

8. The coating of claim 1, wherein the coating includes folds along edges of the sheet.

9. The coating of claim 1, wherein the coating further comprises a deposition texture of a deposition surface of the sheet to improve adhesion of the excess material layer to the deposition surface.

10. The coating of claim 1, wherein the sheet is structured to provide stress relief by allowing expansion and contraction in at least one planar direction of the sheet between the joint locations.

11. (canceled)

12. The coating of claim 1, wherein the sheet includes rigid boundary joints at edges of the sheet, the rigid boundary joints securable to the base material by spot welding.

13. A shielding component for a process chamber comprising:
base material shaped as a shielding component;
a coating covering at least a portion of the base material, the coating comprising:
at least one sheet for receiving excess material, the sheet structured to provide at least one of: i) stress relief; and, ii) resistance to crack propagation, in the excess material; and,
a plurality of joints securing the sheet at joint locations to base material.

14. The shielding component of claim 13, wherein the sheet structure comprises at least one of:
folds;
ribs; and,
bi-facial curves.

15. The shielding component of claim 13, wherein one or more of the plurality of joints comprise folds in the sheet.

16. The shielding component of claim 13, wherein the plurality of joints are secured to the base material by spot welding at the joint locations.

17. The shielding component of claim 16, wherein the spot welds are removable.

18. (canceled)

19. The shielding component of claim 13, wherein the sheet includes as joints folds at one or more of the plurality of joint locations, and at least one of folds, ribs, and bi-facial curves between joint locations.

20. The shielding component of claim 13, wherein the coating includes folds along edges of the sheet.

21. (canceled)

22. The shielding component of claim 13, wherein the sheet is structured to provide the stress relief by allowing expansion and contraction in at least one planar direction of the sheet between the joint locations.

23. (canceled)

24. The coating of claim 13, wherein the sheet is free-standing between the joint locations.

25. (canceled)

26. (canceled)

27. A method for coating a process chamber component comprising:
providing a coating for protecting the process chamber component from excess material, the coating comprising at least one sheet for receiving excess material, the at least one sheet structured to provide at least one of: i) stress relief; and, ii) resistance to crack propagation, in the excess material, and a plurality of joints for securing the at least one sheet at joint locations to the process chamber component; and,
bonding the coating by conforming the coating to a surface of the process chamber component intended to be protected, and spot welding the plurality of joints to the process chamber component.
